(19) United States
(12) Patent Application Publication
(10) Pub. No.: US 2016/0293682 A1
(43) Pub. Date: Oct. 6, 2016

(54) ORGANIC LIGHT-EMITTING DISPLAY DEVICE

(71) Applicant: CORNING PRECISION MATERIALS CO., LTD., Asan-si, Chungcheongnam-do (KR)

(72) Inventor: June Hyong Park, Chungcheongnam-do (KR)

(73) Assignee: Corning Precision Materials Co., Ltd., Chungcheongnam-do (KR)

(21) Appl. No.: 15/036,307

(22) PCT Filed: Nov. 12, 2014
(86) PCT No.: PCT/KR2014/010865

§ 371 Date: May 12, 2016

(30) Foreign Application Priority Data
Nov. 14, 2013 (KR) 10-2013-0138383

(51) Int. Cl. H01L 27/32; H01L 51/52

(52) U.S. Cl. CPC H01L 27/3246; H01L 51/5275; H01L 51/5284; H01L 27/3276

(57) ABSTRACT

The present invention relates to an organic light-emitting display device having excellent efficiency due to improved luminance. To this end, the present invention provides an organic light-emitting display device comprising: a substrate; a plurality of thin-film transistors formed on each of a plurality of pixel areas defined by the intersection of a plurality of gate lines and data lines formed on the substrate; a plurality of organic light-emitting devices formed on the upper surfaces of the thin-film transistors and electrically connected to the respective thin-film transistors; a black matrix layer formed between the adjacent organic light-emitting devices; and a multilayered coating film coated on the surface of the black matrix layer and formed of the lamination of substances that have different refractive indices from each other.

### TECHNICAL FIELD

The present invention relates to an organic light-emitting display device, and more particularly, to an organic light-emitting display device having excellent efficiency due to improved luminance.

### BACKGROUND ART

Generally, an organic light-emitting diode (OLED) includes an anode, an emission layer, and a cathode. When a voltage is induced between the anode and the cathode, holes from the anode migrate to the emission layer through a hole injection layer and a hole transport layer, and electrons from the cathode migrate to the emission layer through an electron injection layer and an electron transport layer. The electrons and the holes that have migrated into the emission layer recombine with each other, thereby generating excitons. When excitons transit from an excited state to a ground state, light is emitted.

Organic light-emitting display devices employing such OLEDs are divided into passive matrix organic light-emitting display devices and active matrix organic light-emitting display devices according to modes for driving N×M number of pixels arranged in a matrix pattern utilized thereby.

In the case of active matrix type organic light-emitting display devices, a pixel electrode defining an emission region and a unit pixel driving circuit for applying an electric current or a voltage to the pixel electrode are disposed in a unit pixel area. Here, the unit pixel driving circuit includes at least two thin-film transistors (TFTs) and a single capacitor to enable the supply of a certain amount of electric current, irrespective of the number of pixels, thereby obtaining a reliable level of luminance. Such active matrix type organic light-emitting display devices are advantageously adaptable to high resolution and large scale displays due to having reduced power consumption.

However, only about 20% of light generated by an OLED is emitted out, while about 80% of the light generated thereby is lost due to a waveguide effect originating from the difference in refractive indices between a glass substrate and an organic light-emitting layer that includes an anode, a hole injection layer, a hole transport layer, an emission layer, an electron transport layer, and an electron injection layer, as well as by total internal reflection originating from the difference in refractive indices between the glass substrate and ambient air. Here, the refractive index of the internal organic light-emitting layer ranges from 1.7 to 1.8, whereas the refractive index of indium tin oxide (ITO), generally used for the anode, is about 1.9. Since the two layers have a significantly low thickness, ranging from 200 nm to 400 nm, and the refractive index of the glass used for the glass substrate is about 1.5, a planar waveguide is thereby formed inside the OLED. It is estimated that the ratio of light lost in the internal waveguide mode due to the above-described reasons is about 45%. In addition, since the refractive index of the glass substrate is about 1.5 and the refractive index of the ambient air is 1.0, when light exits the interior of the glass substrate, a beam of light having an angle of incidence greater than a critical angle may be totally reflected and trapped inside the glass substrate. The ratio of light trapped in this manner is commonly about 35%, and only about 20% of generated light may be emitted out.

Structures, such as those for scattering particles, irregular structural features, or the like, are commonly formed in front of OLEDs in order to improve the light emission efficiency of the OLEDs according to the related art. However, such structures may cause diffused reflection on the background of a screen, and thus are regarded as being unsuitable for use in displays. Further, when such a structure is used in OLEDs having bottom emission structures in order to improve light emission efficiency, a TFT structure may degrade the light emission efficiency of OLEDs, which may be problematic.

### RELATED ART DOCUMENT

Japanese Unexamined Patent Publication No. 1998-214043 (Aug. 11, 1998)

### DISCLOSURE

### Technical Problem

Accordingly, the present invention has been made in consideration of the above problems occurring in the related art, and the present invention proposes an organic light-emitting display device having excellent efficiency due to having improved luminance.

### Technical Solution

According to an aspect of the present invention, the present invention provides an organic light-emitting display device including: a substrate; a plurality of thin-film transistors (TFTs) respectively formed on a plurality of pixel areas defined by intersections between gate lines and data lines formed on the substrate; a plurality of organic light-emitting diodes (OLEDs) formed on the TFTs and electrically connected to the TFTs; black matrix layers alternating with OLEDs; and multilayered coating films coating surfaces of the black matrix layers respectively, each of the multilayered coating films including coating layers having different refractive indices.

Here, the coating layers may include: a first coating layer coating the surface of the black matrix layer; and a second coating layer coating the first coating layer and including a material having a higher refractive index than that of the first coating layer.

The first coating layer may include one selected from among acrylic polymeric materials, SiOx, MgF2, and photosensitive low-refractive photoresists.

The second coating layer may include one selected from among metal oxides, metal nitrides, and polyimide-based high-refractive polymeric materials.

The thicknesses of each of the multilayered coating films may range from 0.1 μm to 5 μm.

Each of the multilayered coating films may have a trench in the upper surface thereof, the trench exposing the black matrix layer in a linear shape.

A passivation layer may be provided between the plurality of TFTs and the plurality of OLEDs.

The black matrix layers may be formed to correspond to the plurality of gate lines and data lines.

Each of the black matrix layers may include an organic or inorganic insulating material.

In addition, the organic light-emitting display device may have a bottom emission structure allowing light to be emitted out through the substrate.

### Advantageous Effects

According to the present invention, the multilayered coating film including coating layers having different refractive indices is formed on the surface of the black matrix layer dividing the OLEDs formed on the pixel areas so that light emitted laterally from the OLEDs due to a waveguide effect and lost by the black matrix layer is refracted forwards. This structure makes it possible to obtain a light-extraction effect at the black matrix layer, thereby improving the luminance of the organic light-emitting display device. Eventually, an organic light-emitting display device exhibiting excellent light emission efficiency can be realized.

### DESCRIPTION OF DRAWINGS

FIG. 1 is a schematic diagram illustrating an organic light-emitting display device according to embodiments of the present invention.

### MODE FOR INVENTION

Hereinafter, an organic light-emitting display device according to an exemplary embodiment of the present invention will be described in detail with reference to the accompanying drawing.

In addition, in the description of the present invention, detailed descriptions of known functions and components will be omitted in the case that the subject matter of the present invention is rendered unclear by the inclusion thereof.

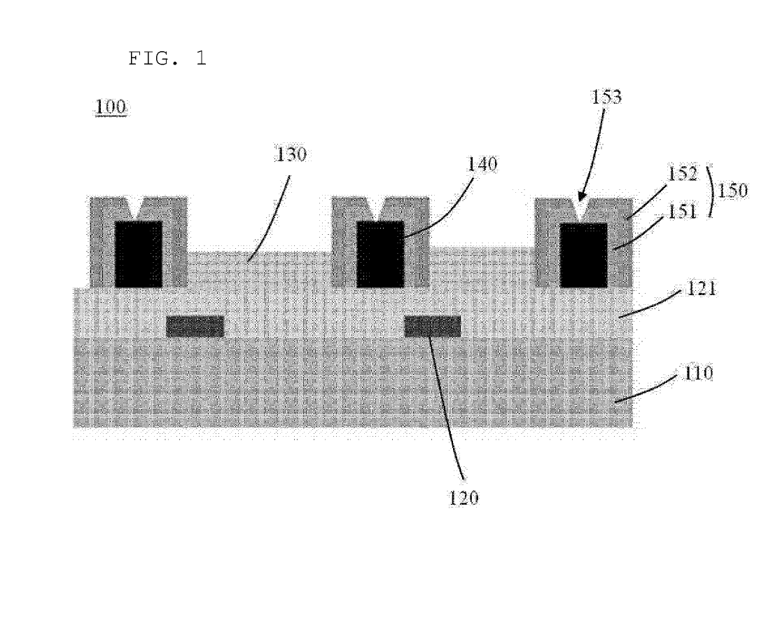

As illustrated in FIG. 1, an organic light-emitting display device 100 according to embodiments of the present invention includes a substrate 110, thin-film transistors (TFTs) 120, organic light-emitting diodes (OLEDs) 130, black matrix layers 140, and multilayered coating films 150.

When the organic light-emitting display device 100 has a bottom emission structure, the substrate 110 serves as a passage through which light generated by the OLEDs 130 is emitted out. In this regard, the substrate 110 is disposed forwardly of the OLEDs 130 (a lower side in the drawing). In addition, the substrate 110 has a plurality of gate lines (not shown) for the transmission of gate signals and a plurality of data lines (not shown) for the transmission of data signals on the upper surface thereof. The gate lines are arranged in parallel with each other, for example, in the horizontal direction, and the data lines are in arranged parallel with each other in the vertical direction. In addition, a plurality of pixel areas are defined on the substrate by the intersections between the gate lines and the data lines.

The substrate 110 is a transparent substrate that may be formed of a glass material mainly composed of, for example, SiO₂. The substrate 110 is not limited thereto, and may be formed of a transparent plastic material. In addition, a buffer layer (not shown) formed of, for example, SiO₂ or SiNₓ, may be formed on the substrate 110 to maintain the flatness of the substrate 110 and prevent impurities from penetrating into the substrate.

The TFTs 120 are respectively formed on the plurality of pixel areas defined by the intersections between the gate lines (not shown) and the data lines (not shown) formed on the substrate 110. Here, a switching transistor and a driving transistor, components of the TFT 120, and a storage capacitor (not shown), are formed on each of the pixel areas.

Here, although not specifically illustrated, the TFT 120 may include a semiconductor layer, a gate dielectric film, a gate electrode, an interlayer dielectric film, a source electrode, and a drain electrode. The semiconductor layer is formed on the buffer layer (not shown) in a certain pattern. Such a semiconductor layer may be formed of an inorganic semiconductor material, such as amorphous silicon or poly-crystal silicon, or an organic semiconductor material, and includes a source region, a drain region, and a channel region. The gate dielectric formed of, for example, SiO₂ or SiNₓ is formed on the semiconductor layer, and the gate electrode is formed in a certain region of the upper portion of the gate dielectric film. The gate electrode is connected to the gate line (not shown), through which ON/OFF signals are applied to the TFT 120. In addition, the interlayer dielectric film is formed on the gate electrode such that the source and drain electrodes respectively abut the source and drain regions of the semiconductor layer via contact holes.

In addition, the TFT 120 having the above-mentioned structure is covered with and protected by a passivation film 121. The passivation film 121 may be an organic or inorganic insulation film. The inorganic insulation film may contain SiO₂, SiNₓ, SiON, Al₂O₃, TiO₂, Ta₂O₅, HfO₂, ZrO₂, BST, PZT, and the like, and the organic insulation film may contain at least one selected from among general-purpose polymers, such as PMMA and PS, polymeric derivatives having phenol groups, acrylic polymers, aryl ether based polymers, amide based polymers, fluorine based polymers, p-xylene based polymers, vinyl alcohol based polymers, and blends thereof. In addition, the passivation film 121 may be formed as a composite structure consisting of an inorganic insulation layer and an organic insulation layer.

The OLEDs 130 are formed on the upper portion of the TFT 120, more particularly, on the passivation film 121. The OLEDs 130 are respectively formed on the pixel areas, such that an OLED in each pixel area is electrically connected to the TFT 120 formed on the same pixel area. Although not illustrated, each of the OLEDs 130 includes a first electrode, an organic light-emitting layer, and a second electrode.

The first electrode is formed on the passivation film 121 to match the corresponding pixel area. In addition, the first electrode is electrically connected to the drain electrode of the TFT 120 via a contact hole. The first electrode is a transparent electrode acting as an anode of the OLED. The first electrode may be formed of, for example, indium tin oxide (ITO) having a greater work function to facilitate hole injection into the OLED.

The organic light-emitting layer is formed on the first electrode. The organic light-emitting layer may include a hole injection layer, a hole transport layer, an emission layer, an electron transport layer, and an electron injection layer, sequentially laminated on the first electrode. With this structure, when a forward voltage is induced between the first electrode acting as an anode and the second electrode acting as a cathode, electrons from the cathode migrate to the emission layer through the electron injection layer and the electron transport layer, and holes from the anode migrate to the emission layer through the hole injection layer and the hole transport layer. The electrons and the holes that have migrated into the emission layer recombine with each other, thereby generating excitons. When excitons transit from an excited state to a ground state, light is emitted. The brightness of emitted light is proportional to the amount of current that flows between the anode and the cathode. Here, when the OLED 130 is a white OLED, the light-emitting layer may have, for example, a laminated structure including a high-molecular light-emitting layer that emits blue light and a low-molecular light-emitting layer that emits orange-red light, as well as a variety of other structures, to emit white light. In addition, the organic light-emitting layer may have a tandem structure. That is, the organic light-emitting layer may be formed as a plurality of organic light-emitting layers, and alternate with interconnecting layers acting as charge generation layers.

The second electrode is formed on the organic light-emitting layer. Here, the second electrode may be formed on the entire area of the plurality of OLEDs 130. The second electrode acts as a cathode of the OLED 130, and may be a metal thin film formed of Al, Al:Li or Mg:Ag that has a smaller work function in order to facilitate electron injection into the organic light-emitting layer.

The black matrix layers 140 are formed to alternate with the OLEDs 130. The black matrix layers 140 are arranged to correspond to the plurality of gate lines (not shown) and the plurality of data lines (not shown) formed on the substrate 110. That is, the black matrix layers 140 are provided in a pattern, similar to banks, surrounding the pixel areas defined by the intersections between the gate lines (not shown) and the data lines (not shown), thereby defining respective pixel areas. Thus, the OLED 130 is formed on the passivation film 121 that is a pixel area exposed as an open region by the black matrix layer 140. The black matrix layer 140 may be formed of an organic dielectric material having heat resistance and solvent resistance, such as an acrylic resin, a polyimide resin, or the like, or an inorganic dielectric material, such as SiO₂, TiO₂, or the like.

The surfaces of the black matrix layers 140 are coated with the multilayered coating films 150. In addition, each of the multilayered coating films 150 consists of coating layers having different refractive indices. The thickness of the multilayered coating film 150 ranges from 0.1 μm to 5 μm.

The multilayered coating film 150 may include a first coating layer 151 and a second coating layer 152.

Here, the first coating layer is formed to coat the surface of the black matrix layer 140. The first coating layer 151 may be formed of a material having a lower refractive index than the refractive index of the second coating layer 152. For example, the first coating layer 151 may be formed of one selected from among acrylic polymeric material, SiOₓ, MgF₂, and a photosensitive, low-refractive photoresist. The first coating layer 151 serves to allow light refracted from an edge of the pixel area of the first coating layer 151, i.e. a lateral side of the OLED 130, by the second coating layer 152 to propagate linearly.

The second coating layer 152 is formed to coat the surface of the first coating layer 151. Thus, the multilayered coating film 150 forms a two-layer structure. In addition, the second coating layer 152 may be formed of a material having a higher refractive index than the refractive index of the first coating layer 151. For example, the second coating layer 152 may be formed of one selected from the group consisting of metal oxides, such as ZnO or TiO₂, metal nitrides, such as Si₃N₄, and a polyimide-based high-refractive polymeric material. The second coating layer 152 serves to trap light emitted laterally from the OLED 130 due to a waveguide effect.

Like this, when the multilayered coating film 150 having the first coating layer 151 and the second coating layer 152 with different refractive indices is formed on the surface of the black matrix layer 140, it is possible to refract light forwardly that would otherwise be emitted from the OLEDs 130 laterally due to the waveguide effect and lost by the black matrix layer 140. That is, when the multilayered coating film 150 is formed on the surface of the black matrix layer 140, a light-extraction effect at the black matrix layer 140 can be obtained, thereby improving the overall light-extraction efficiency of the OLEDs 130, and the luminance of the organic light-emitting display device 100 is thus improved, eventually improving the light emission efficiency of the organic light-emitting display device 100.

In addition, in the embodiment of the present invention, a trench 153, i.e. a “V” type wedge or groove (based on a cross section), is formed in one side of the multilayered coating film 150 that does not abut the OLED 130, i.e. in the upper surface of the multilayered coating film 150 on the basis of the drawing. The trench 153 exposes a linearly shaped portion of the black matrix layer 140. The trench 153 serves to reflect rearwardly-refracted light in the forward direction again, thereby further improving the light-extraction efficiency at the black matrix layer 140.

The foregoing descriptions of specific exemplary embodiments of the present invention have been presented with respect to the drawing. They are not intended to be exhaustive or to limit the present invention to the precise forms disclosed herein, and many modifications and variations are obviously possible for a person having ordinary skill in the art in light of the above teachings.

It is intended therefore that the scope of the present invention should not be limited to the foregoing embodiments, but shall be defined by the Claims appended hereto and their equivalents.

1. An organic light-emitting display device comprising:
a substrate;
a plurality of thin-film transistors respectively formed on a plurality of pixel areas defined by intersections between gate lines and data lines formed on the substrate;
a plurality of organic light-emitting diodes formed over the thin-film transistors and electrically connected to the thin-film transistors;
black matrix layers alternating with organic light-emitting diodes; and
multilayered coating films coating surfaces of the black matrix layers respectively, each of the multilayered coating films comprising coating layers having different refractive indices.

2. The organic light-emitting display device according to claim 1, wherein the coating layers comprises:
a first coating layer coating the surface of the black matrix layer; and
a second coating layer coating the first coating layer and comprising a material having a higher refractive index than that of the first coating layer.

3. The organic light-emitting display device according to claim 2, wherein the first coating layer comprises one selected from the group consisting of acrylic polymeric materials, SiOx, MgF2, and photosensitive low-refractive photoresists.

4. The organic light-emitting display device according to claim 2, wherein the second coating layer comprises one selected from the group consisting of metal oxides, metal nitrides, and polyimide-based high-refractive polymeric materials.

5. The organic light-emitting display device according to claim 1, wherein a thicknesses of each of the multilayered coating films range from 0.1 μm to 5 μm.

6. The organic light-emitting display device according to claim 1, wherein each of the multilayered coating films comprises a trench in an upper surface thereof, the trench exposing the black matrix layer in a linear shape.

7. The organic light-emitting display device according to claim 1, wherein a passivation layer is provided between the plurality of thin-film transistors and the plurality of organic light-emitting diodes.

8. The organic light-emitting display device according to claim 1, wherein the black matrix layers are formed to correspond to the plurality of gate lines and data lines.

9. The organic light-emitting display device according to claim 8, wherein each of the black matrix layers comprises an organic or inorganic insulating material.

10. The organic light-emitting display device according to claim 1, wherein the organic light-emitting display device has a bottom emission structure allowing light to be emitted out through the substrate.
